(19) United States
(12) Patent Application Publication
(10) Pub. No.: US 2024/0421075 A1
(43) Pub. Date: Dec. 19, 2024

(54) SEMICONDUCTOR DEVICE AND MANUFACTURING METHOD OF SEMICONDUCTOR DEVICE

(71) Applicant: LAPIS SEMICONDUCTOR CO., LTD., Yokohama-shi (JP)

(72) Inventors: Reiji YANO, Yokohama-shi (JP); Kinya ASHIKAGA, Yokohama-shi (JP)

(21) Appl. No.: 18/816,466

(22) Filed: Aug. 27, 2024

Related U.S. Application Data
(63) Continuation of application No. PCT/JP2023/007392, filed on Feb. 28, 2023.

(30) Foreign Application Priority Data
Feb. 28, 2022 (JP) 2022-029045

(51) Int. Cl. H01L 23/525

(52) U.S. Cl. CPC H01L 23/5256

(57) ABSTRACT

A semiconductor device includes a semiconductor substrate having one principal surface on which a groove portion is formed, a plurality of fuse wirings formed in the groove portion, a metal wiring disposed at a position separated from the groove portion and exposed on the one principal surface, a first insulating film covering the one principal surface and having a first opening that exposes the plurality of fuse wirings and a second opening that exposes the metal wiring, a polymeric insulating film in the first opening burying the plurality of fuse wirings in the groove portion, a first metal portion covering the polymeric insulating film, a second metal portion extending so as to cover a surface of the metal wiring exposed in the second opening and a surface of the first insulating film at a peripheral edge of the second opening, a second insulating film burying the first metal portion on an upper surface of the polymeric insulating film and covering the second metal portion so as to partially expose an upper surface thereof, and a third metal portion ranging from an upper surface of the second metal portion exposed from the second insulating film to an upper surface of the second insulating film.

### TECHNICAL FIELD

The present disclosure relates to a semiconductor device, in particular, an MIM capacitor having a fuse portion and a manufacturing method thereof.

### BACKGROUND ART

There has been known a semiconductor device having a Metal Insulator Metal (MIM) structure as a semiconductor capacitor. In the semiconductor device with a MIM structure, a plurality of metal layers are formed, and an insulating layer is formed between the metal layers (for example, Patent Document 1).
Patent Document 1: Japanese Unexamined Patent Application Publication No 2007-208190

In the semiconductor device with a MIM structure having a plurality of metal layers, a polyimide film is formed between a first metal layer formed at a position close to a substrate among the plurality of metal layers and a second metal layer formed as an upper layer on the first metal layer. When the second metal layer is etched in a wiring portion, film thinning occurs on the polyimide film. In addition, side etching is caused on the polyimide film in a lower portion of the second metal layer by ashing and organic stripping after etching. Accordingly, there has been a problem of coverage becoming insufficient when a SiO2 film is formed on the second metal layer, resulting in poor coverage of a third metal layer and generation of step disconnection.

Moreover, there has been a problem that degassed gas is generated in the polyimide film because high-temperature treatment is performed in a step of forming the SiO2 film, and the stress of the degassed gas causes delamination of the second metal layer (metal delamination).

The present disclosure has been made in consideration of the above-described problems and an object of which is to provide a semiconductor device that can reduce generation of step disconnection and metal delamination, which occur in a wiring layer, in a semiconductor device with a MIM structure.

### SUMMARY

A semiconductor device according to the present disclosure includes a semiconductor substrate having one principal surface on which a groove portion is formed, a plurality of fuse wirings formed in the groove portion, a metal wiring disposed at a position separated from the groove portion of the one principal surface and exposed on the one principal surface, a first insulating film formed so as to cover the one principal surface and having a first opening that exposes the plurality of fuse wirings and a second opening that exposes the metal wiring, a polymeric insulating film formed in the first opening so as to bury the plurality of fuse wirings in the groove portion, a first metal portion formed so as to cover the polymeric insulating film, a second metal portion extending so as to cover a surface of the metal wiring exposed in the second opening and a surface of the first insulating film at a peripheral edge of the second opening, a second insulating film burying the first metal portion on an upper surface of the polymeric insulating film and covering the second metal portion so as to partially expose an upper surface of the second metal portion, and a third metal portion ranging from an upper surface of the second metal portion exposed from the second insulating film to an upper surface of the second insulating film.

A manufacturing method of a semiconductor device according to the present disclosure includes: a first step of preparing a semiconductor substrate having a groove portion formed on one principal surface; a second step of forming a first metal layer on the one principal surface of the semiconductor substrate to form a plurality of fuse wirings made of the first metal layer in the groove portion and forming a metal wiring made of the first metal layer on the one principal surface at a position separated from the groove portion of the one principal surface; a third step of forming a first insulating film so as to cover the one principal surface and have a first opening that exposes the plurality of fuse wirings and a second opening that exposes the metal wiring; a fourth step of forming a polymeric insulating film in the first opening so as to bury the plurality of fuse wirings in the groove portion; a fifth step of forming a second metal portion by forming a second metal layer so as to extend covering a first metal portion covering the polymeric insulating film, a surface of the metal wiring exposed in the second opening, and a surface of the first insulating film at a peripheral edge of the second opening; a sixth step of forming a second insulating film that buries the first metal portion on an upper surface of the polymeric insulating film and covers the second metal portion so as to partially expose an upper surface of the second metal portion; and a seventh step of forming a third metal portion by forming a third metal layer, the third metal portion ranging from an upper surface of the second metal portion exposed from the second insulating film to an upper surface of the second insulating film.

### BRIEF DESCRIPTION OF THE DRAWINGS

FIG. 1 is a cross-sectional view illustrating a configuration of a semiconductor device.

FIG. 2 is a cross-sectional view illustrating a configuration of a fuse portion.

FIG. 3 is a cross-sectional view illustrating a configuration of a wiring portion.

FIG. 4 is a flowchart illustrating manufacturing steps of the semiconductor device.

FIG. 5A is a cross-sectional view of the semiconductor device in a first metal layer formation step.

FIG. 5B is a cross-sectional view of the semiconductor device in a SiN formation step.

FIG. 5C is a cross-sectional view of the semiconductor device in a lower layer polyimide formation step.

FIG. 5D is a cross-sectional view of the semiconductor device in a lower layer polyimide removing step.

FIG. 6A is a cross-sectional view of the semiconductor device in a second metal layer formation step.

FIG. 6B is a cross-sectional view of the semiconductor device in an etching step.

FIG. 6C is a cross-sectional view of the semiconductor device after the etching step.

FIG. 7A is a cross-sectional view of the semiconductor device in a SiO2 film formation step.

FIG. 7B is a cross-sectional view of the semiconductor device in a third metal layer formation step.

FIG. 7C is a cross-sectional view of the semiconductor device in an upper layer polyimide formation step.

FIG. 8 is a cross-sectional view illustrating configurations of a fuse portion and a wiring portion of a semiconductor device of a comparative example.

FIG. 9A is a diagram illustrating a problem that occurs in the semiconductor device of the comparative example.

FIG. 9B is a diagram illustrating a problem that occurs in the semiconductor device of the comparative example.

FIG. 9C is a diagram illustrating a problem that occurs in the semiconductor device of the comparative example.

FIG. 10A is a diagram illustrating a problem that occurs in the semiconductor device of the comparative example.

FIG. 10B is a diagram illustrating a problem that occurs in the semiconductor device of the comparative example.

FIG. 10C is a diagram illustrating a problem that occurs in the semiconductor device of the comparative example.

### DETAILED DESCRIPTION

The following describes preferred embodiments of the present disclosure in detail. In the description and attached drawings of each embodiment below, same reference numerals are given to actually same or equivalent parts.

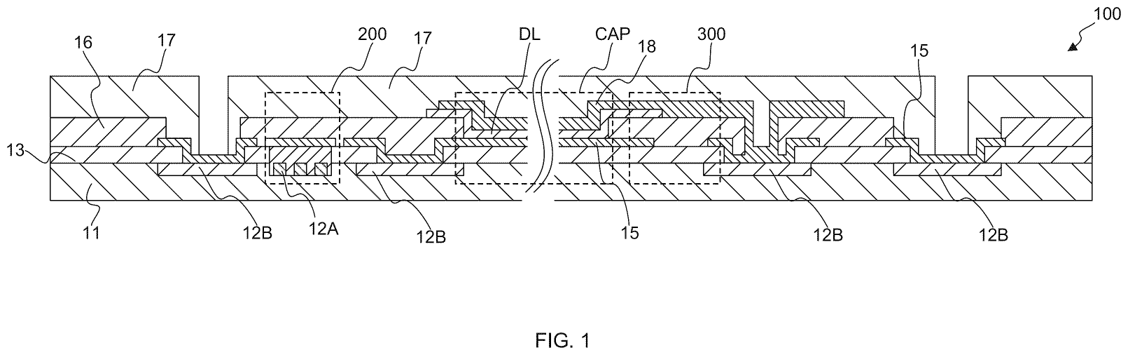

FIG. 1 is a cross-sectional view of a semiconductor device 100 according to an embodiment of the present disclosure. The semiconductor device 100 is a semiconductor device with a Metal Insulator Metal (MIM) structure that has a structure composed of a plurality of metal layers and interlayer insulating films formed between the plurality of metal layers. The semiconductor device 100 has a semiconductor substrate 11, a plurality of fuse wirings 12A made of a first metal layer, a metal wiring 12B similarly made of the first metal layer, a SiN film 13 that is a first interlayer insulating film, a second metal layer 15, a SiO2 film 16 that is a second interlayer insulating film, and a third metal layer 18. In addition, a lower layer polyimide film 14 is formed in a formation region of the fuse wirings 12A, and an upper layer polyimide film 17 is formed so as to cover an upper surface of the SiO2 film 16 and the third metal layer 18.

The semiconductor device 100 has a fuse portion 200, which is a region in which the plurality of fuse wirings 12A are formed, and a wiring portion 300, which is a region in which the metal wiring 12B is formed. A capacitor (indicated as CAP in the drawing) is formed between the fuse portion 200 and the wiring portion 300 with a dielectric DL sandwiched between the second metal layer 15 as a lower electrode and the third metal layer 18 as an upper electrode.

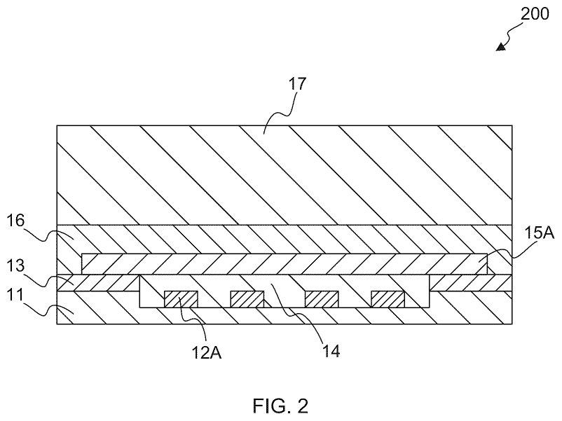

FIG. 2 is an enlarged cross-sectional view illustrating a configuration of the fuse portion 200. The fuse portion 200 is constituted of the semiconductor substrate 11, the fuse wirings 12A, the SiN film 13, the lower layer polyimide film 14, a metal portion 15A, the SiO2 film 16, and the upper layer polyimide film 17.

The semiconductor substrate 11 is a Si substrate made of silicon (Si). In the fuse portion 200, a groove portion that becomes a formation region of the fuse wirings 12A is formed on one principal surface (hereinafter referred to as an upper surface) of the semiconductor substrate 11.

The plurality of fuse wirings 12A are formed in the groove portion. The fuse wirings 12A are constituted of the first metal layer (referred to as a first metal layer 12 in the following description) made of aluminum (Al).

The SiN film 13 is the first interlayer insulating film disposed in the semiconductor device 100 having a MIM structure. In the fuse portion 200, the SiN film 13 is formed on the upper surface of the semiconductor substrate 11 in a region other than the groove portion. In other words, the SiN film 13 has an opening portion (first opening) that exposes the fuse wirings 12A.

The lower layer polyimide film 14 is a polymeric insulating film formed in the fuse portion 200. The lower layer polyimide film 14 is formed so as to bury the plurality of fuse wirings 12A in the groove portion of the semiconductor substrate 11.

The metal portion 15A is formed so as to cover the lower layer polyimide film 14 in the fuse portion 200. The metal portion 15A is constituted of the second metal layer 15 made of Al—Cu alloy.

The SiO2 film 16 is the second interlayer insulating film disposed in the semiconductor device 100 having a MIM structure. The SiO2 film 16 is formed so as to bury the metal portion 15A on an upper surface of the lower layer polyimide film 14.

The upper layer polyimide film 17 is formed on an upper surface of the SiO2 film 16.

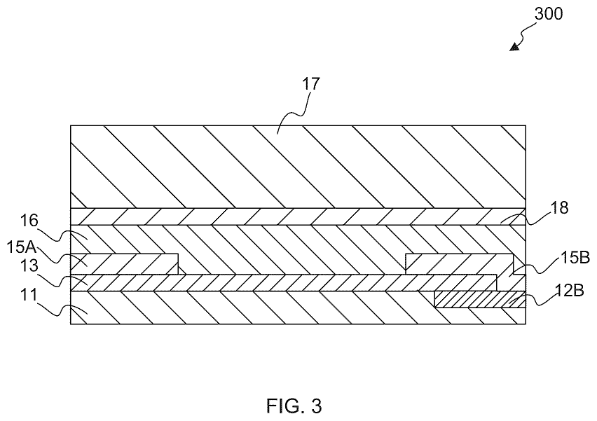

FIG. 3 is a cross-sectional view illustrating a configuration of the wiring portion 300. The wiring portion 300 is constituted of the semiconductor substrate 11, the metal wiring 12B, the SiN film 13, a metal portion 15B, the SiO2 film 16, the upper layer polyimide film 17, and the third metal layer 18.

The metal wiring 12B is formed at a position separated from the groove portion (that is, the formation region of the fuse wirings 12A) on the upper surface of the semiconductor substrate 11. The metal wiring 12B is constituted of the first metal layer 12, similarly to the fuse wirings 12A in the fuse portion 200.

The SiN film 13 covers an upper surface of the metal wiring 12B and exposes a part of the metal wiring 12B in the wiring portion 300. In other words, the SiN film 13 has an opening portion (second opening) that exposes a part of the metal wiring 12B.

The metal portion 15B extends so as to cover a surface of the metal wiring 12B exposed from the opening portion of the SiN film 13 and a surface of the SiN film 13 at a peripheral edge of the opening portion. The metal portion 15B is constituted of the second metal layer 15, similarly to the metal portion 15A in the fuse portion 200. The metal portion 15B is connected to the lower electrode that constitutes the capacitor CAP illustrated in FIG. 1.

The SiO2 film 16 is formed so as to cover upper surfaces of the metal portion 15B and the SiN film 13 in the wiring portion 300. In addition, as illustrated in FIG. 1, the SiO2 film 16 is formed such that the upper surface of the metal portion 15B is partially exposed in a region outside the wiring portion 300.

The third metal layer 18 is formed on the upper surface of the SiO2 film 16. As illustrated in FIG. 1, the third metal layer 18 has a shape extending from the upper surface of the metal portion 15B to the upper surface of the SiO2 film 16 in the region outside the wiring portion 300 and is connected to the upper electrode constituting the capacitor CAP.

In the wiring portion 300, the upper surface of the metal wiring 12B made of the first metal layer 12 is in contact with the SiN film 13 or the metal portion 15B and is coated by the SiN film 13 and the metal portion 15B. That is, in the wiring portion 300, unlike the fuse portion 200, the lower layer polyimide film 14 is not formed.

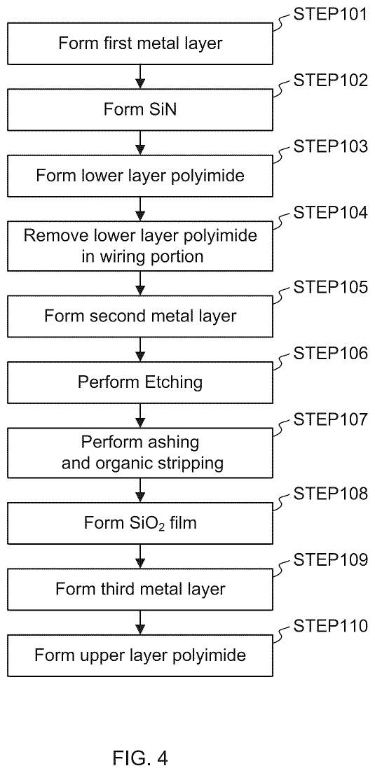

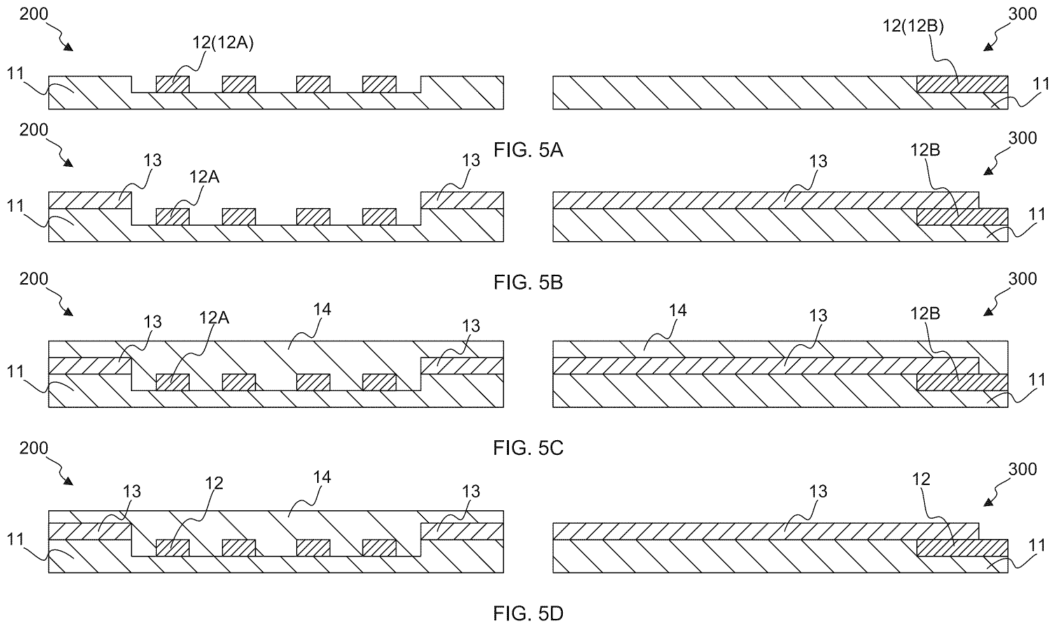

Next, a manufacturing method of the semiconductor device 100 of the embodiment will be described. FIG. 4 is a flowchart illustrating a procedure of the manufacturing method. FIGS. 5A to 5D, FIGS. 6A to 6C, and FIGS. 7A to 7C are cross-sectional views of each of the fuse portion 200 and the wiring portion 300 in the flowchart of FIG. 4.

First, the semiconductor substrate 11 having a groove portion at a formation position of the fuse portion 200 is prepared. Then, the first metal layer 12 is formed on the upper surface of the semiconductor substrate 11 by sputtering (STEP 101). Accordingly, as illustrated in FIG. 5A, the plurality of fuse wirings 12A are formed in the groove portion disposed in the region corresponding to the fuse portion 200, and the metal wiring 12B is formed on the upper surface of the semiconductor substrate 11 in the region corresponding to the wiring portion 300.

Next, the SiN film 13 is formed so as to cover the upper surface of the semiconductor substrate 11 and have the first opening that exposes the plurality of fuse wirings 12A and the second opening that exposes the metal wiring 12B (STEP 102). Accordingly, a wafer having the SiN film 13 is formed as illustrated in FIG. 5B.

Next, the lower layer polyimide film 14 is formed on an upper surface of the wafer illustrated in FIG. 5B (STEP 103). Accordingly, as illustrated in FIG. 5C, the lower layer polyimide film 14 is formed over upper surfaces of the formation region of the fuse portion 200 and the formation region of the wiring portion 300.

Next, the lower layer polyimide film 14 is removed from the formation region of the wiring portion 300 (STEP 104). Accordingly, as illustrated in FIG. 5D, a wafer is formed, which has the lower layer polyimide film 14 that buries the plurality of fuse wirings 12A and the groove portion in the formation region of the fuse portion 200 and does not have the lower layer polyimide film 14 in the formation region of the wiring portion 300.

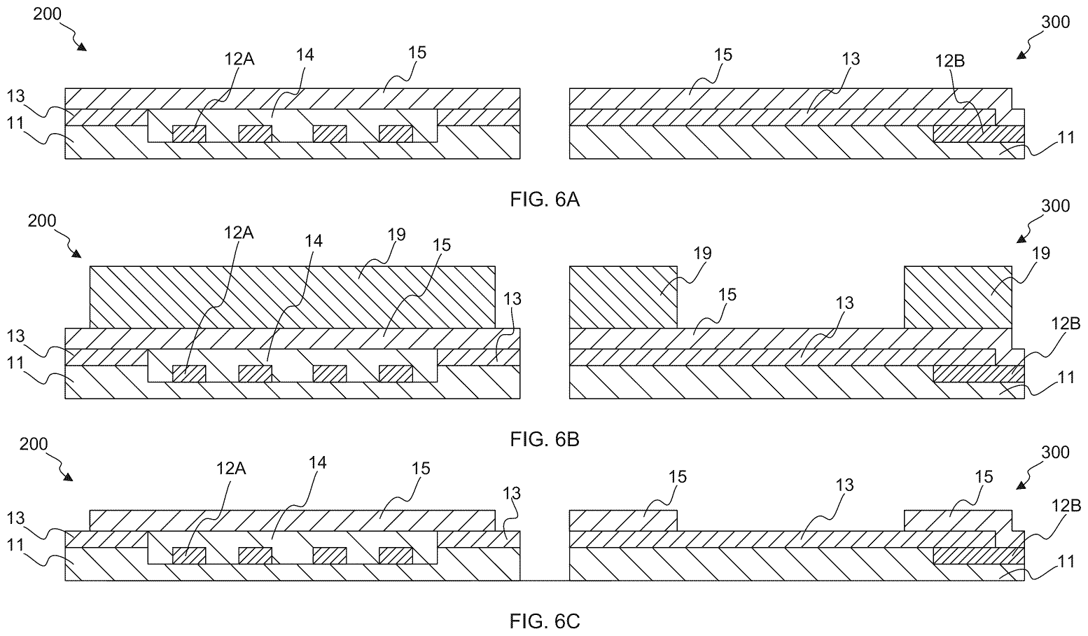

Next, the second metal layer 15 is formed on an upper surface of the wafer illustrated in FIG. 5D (STEP 105). Accordingly, as illustrated in FIG. 6A, the second metal layer 15 is formed over the upper surfaces of the lower layer polyimide film 14 and the SiN film 13 in the formation region of the fuse portion 200, and the second metal layer 15 is formed on the upper surface of the SiN film 13 in the formation region of the wiring portion 300.

Next, as illustrated in FIG. 6B, a positive resist 19 is formed on the second metal layer 15 in the formation region of the wiring portion 300 and etched (STEP 106).

Next, ashing and organic stripping are performed on the wafer after the etching in STEP 106 is performed (STEP 107). Accordingly, as illustrated in FIG. 6C, a wafer is formed, in which a part of the second metal layer 15 is removed in the formation region of the wiring portion 300.

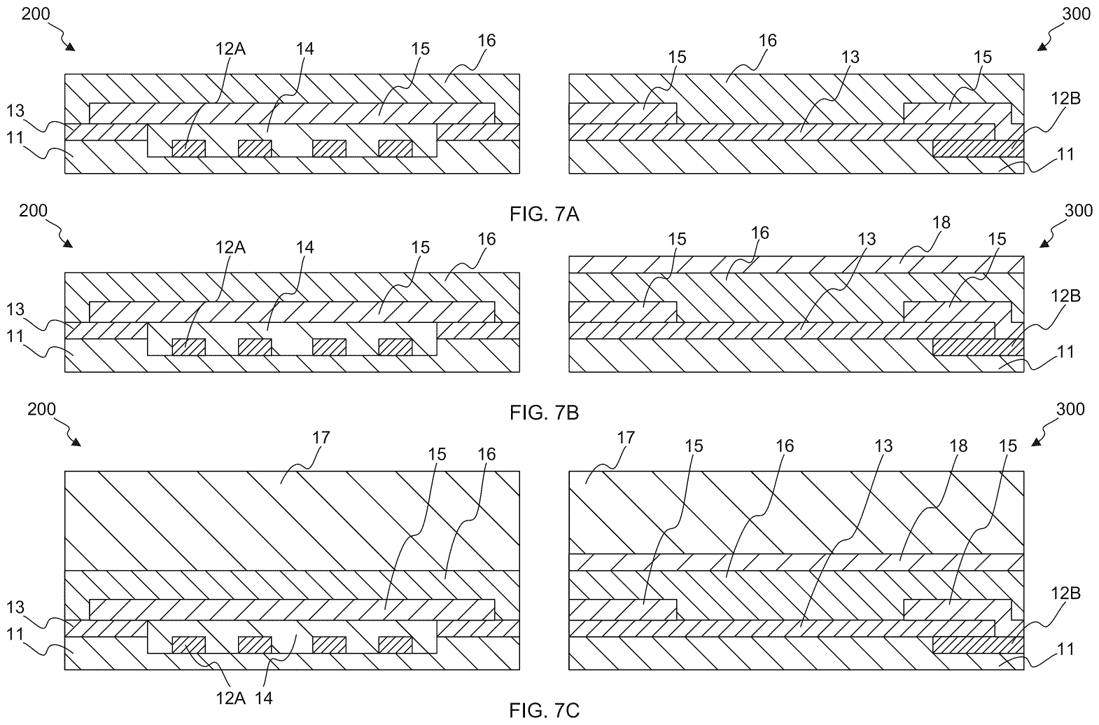

Next, the SiO2 film 16 is formed on an upper surface of the wafer illustrated in FIG. 6C (STEP 108). Accordingly, as illustrated in FIG. 7A, the SiO2 film 16 is formed on the upper surface of the wafer over the fuse portion 200 and the wiring portion 300.

Next, the third metal layer 18 is formed on the upper surface of the SiO2 film 16 in a second region that is the formation region of the wiring portion 300 (STEP 109). Accordingly, as illustrated in FIG. 7B, the third metal layer 18 is formed in the wiring portion 300.

Next, the upper layer polyimide film 17 is formed on an upper surface of the wafer illustrated in FIG. 7B (STEP 110). Accordingly, as illustrated in FIG. 7C, a wafer is formed, in which the upper layer polyimide film 17 is formed over the upper surfaces of the fuse portion 200 and the wiring portion 300.

The semiconductor device 100 is manufactured through the steps described above.

In the semiconductor device 100 of the embodiment, after the lower layer polyimide film 14 is formed on the SiN film 13, the lower layer polyimide film 14 in the wiring portion 300 is removed. Therefore, in the subsequent steps of etching, ashing, and organic stripping of the second metal layer 15, film thinning does not occur on the lower layer polyimide film 14 in the wiring portion 300. This is described below.

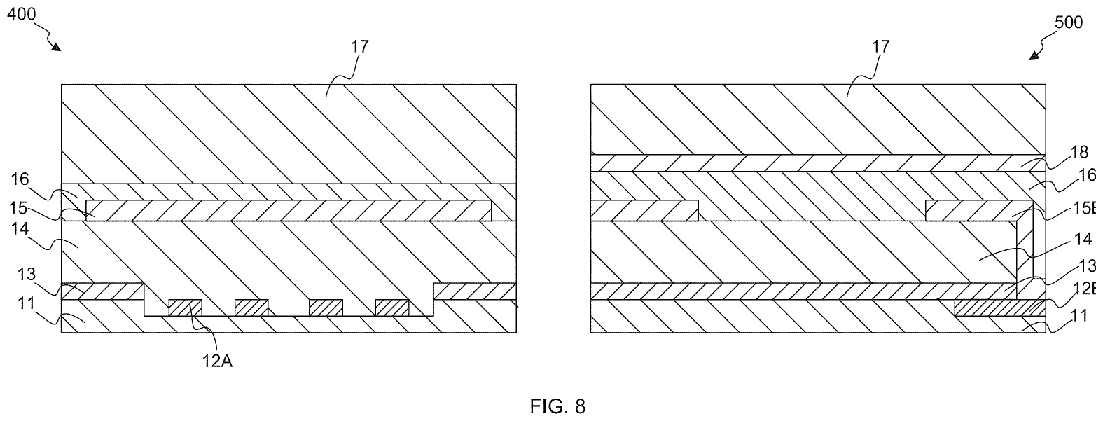

FIG. 8 is a cross-sectional view illustrating respective configurations of a fuse portion 400 and a wiring portion 500 of a semiconductor device of a comparative example. The semiconductor device of the comparative example has a structure in which the lower layer polyimide film 14 is formed (that is, not removed) in the wiring portion 300, unlike the semiconductor device 100 of the embodiment.

In the semiconductor device of the comparative example, the lower layer polyimide film 14 is formed on the upper surface of the semiconductor substrate 11 such that a plurality of fuse wirings 12A made of the first metal layer 12 and the groove portion formed in the semiconductor substrate 11 are buried in the fuse portion 400. In this respect, the semiconductor device of the comparative example has a configuration similar to that of the semiconductor device 100 of the embodiment.

On the other hand, in the semiconductor device of the comparative example, the lower layer polyimide film 14 is formed between the SiN film 13 and the metal portion 15B (the second metal layer 15) with the SiO2 film 16 in the wiring portion 500.

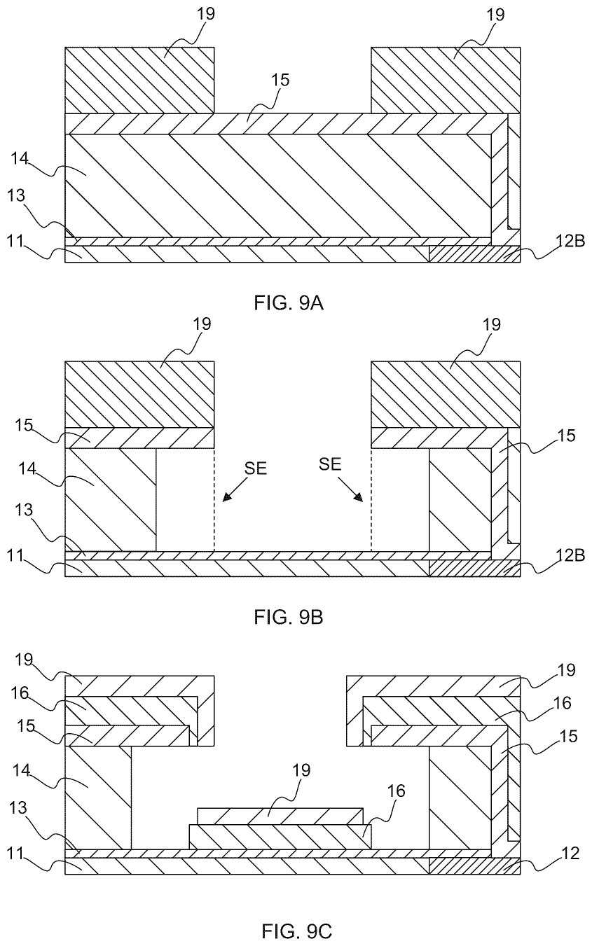

FIGS. 9A to 9C are diagrams schematically illustrating a first problem that occurs in the semiconductor device of the comparative example.

FIG. 9A is a diagram illustrating the etching step of the second metal layer 15. In the etching step, over-etching occurs, causing film thinning of the lower layer polyimide film 14.

FIG. 9B is a diagram illustrating the step of ashing and organic stripping after the etching. In the step, the film thinning of the lower layer polyimide film 14 further progresses, causing side etching (indicated as SE in the drawing) in a part positioned immediately below the second metal layer 15.

FIG. 9C is a cross-sectional view illustrating a state of the wiring portion 500 after the above two steps are performed, and further, the SiO2 film 16 and the third metal layer 18 are formed. The film thinning and the side etching caused in the lower layer polyimide film 14 cause insufficient coverage of the SiO2 film 16. As a result, a so-called “step disconnection” occurs, in which the third metal layer 18 is not partially formed.

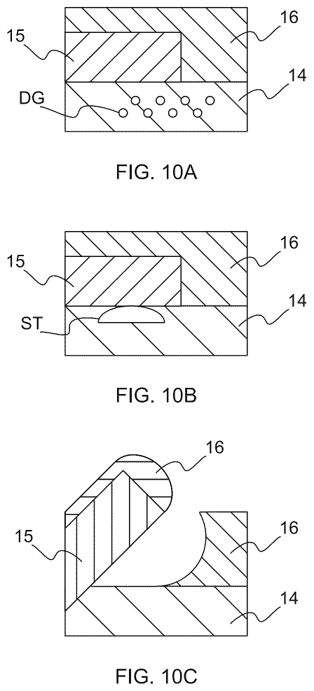

FIGS. 10A to 10C are diagrams schematically illustrating a second problem that occurs in the semiconductor device of the comparative example.

In the formation step of the SiO2 film 16, high-temperature treatment is performed on a wafer. At that time, as illustrated in FIG. 10A, degassed gas (indicated as DG in the drawing) is generated in the lower layer polyimide film 14 in the wiring portion 500.

As illustrated in FIG. 10B, aggregation of the degassed gas generated in the lower layer polyimide film 14 generates stress (indicated as ST in the drawing) in a direction from the lower layer polyimide film 14 toward a lower surface of the second metal layer 15.

As a result, metal delamination occurs due to the stress of the degassed gas generated in the lower layer polyimide film 14, and as illustrated in FIG. 10C, a part of the second metal layer 15 is delaminated.

In contrast to this, in the semiconductor device 100 of the embodiment, since the lower layer polyimide film 14 is not formed in the wiring portion 300, the first problem and the second problem that occur in the comparative example do not occur.

Although the lower layer polyimide film 14 is disposed in the fuse portion 200, the area of the fuse portion 200 that is occupied in the semiconductor device 100 is extremely small (for example, less than 1%). Accordingly, the above-described problems caused by the lower layer polyimide film 14 rarely occur, and even if they occur, their effects are extremely small.

Therefore, with the semiconductor device 100 of the embodiment, generation of step disconnection and metal delamination, which occur in a wiring layer due to a lower layer polyimide film, can be reduced.

The present disclosure is not limited to that illustrated in the above-described embodiment. For example, in the above-described embodiment, a case where the first metal layer 12 is constituted of Al and the second metal layer 15 and the third metal layer 18 are constituted of Al—Cu alloy has been described as an example. However, the types of metals that constitute the respective metal layers are not limited thereto.

In addition, in the above-described embodiment, a case where the first interlayer insulating film is constituted of the SiN film 13 and the second interlayer insulating film is constituted of the SiO2 film has been described as an example. However, the configurations of the respective interlayer insulating films are not limited thereto.

### DESCRIPTION OF REFERENCE SIGNS

100 Semiconductor device
200 Fuse portion
300 Wiring portion
11 Semiconductor substrate
12 First metal layer
12A Fuse wiring
12B Metal wiring
13 SiN film
14 Lower layer polyimide film
Second metal layer
15A, 15B Metal portion
16 SiO2 film
17 Upper layer polyimide film
18 Third metal layer
19 Positive resist

1. A semiconductor device comprising:
a semiconductor substrate having one principal surface on which a groove portion is formed;
a plurality of fuse wirings formed in the groove portion;
a metal wiring disposed at a position separated from the groove portion of the one principal surface and exposed on the one principal surface;
a first insulating film formed so as to cover the one principal surface and having a first opening that exposes the plurality of fuse wirings and a second opening that exposes the metal wiring;
a polymeric insulating film formed in the first opening so as to bury the plurality of fuse wirings in the groove portion;
a first metal portion formed so as to cover the polymeric insulating film;
a second metal portion extending so as to cover a surface of the metal wiring exposed in the second opening and a surface of the first insulating film at a peripheral edge of the second opening;
a second insulating film burying the first metal portion on an upper surface of the polymeric insulating film and covering the second metal portion so as to partially expose an upper surface of the second metal portion; and
a third metal portion ranging from an upper surface of the second metal portion exposed from the second insulating film to an upper surface of the second insulating film.

2. The semiconductor device according to claim 1, wherein
the polymeric insulating film is a polyimide film.

3. The semiconductor device according to claim 1, wherein
the first insulating film and the second insulating film are oxide films having a thinner film thickness than the polymeric insulating film.

4. The semiconductor device according to claim 1, wherein
the first insulating film and the second insulating film are nitride films having a thinner film thickness than the polymeric insulating film.

5. The semiconductor device according to any one of claim 1, wherein
the third metal portion extends toward the first opening, and a capacitor is formed by the third metal portion, a dielectric portion formed under the third metal portion, and an electrode layer formed on a surface of the first insulating film under the dielectric portion.

6. A manufacturing method of a semiconductor device, comprising:
a first step of preparing a semiconductor substrate having a groove portion formed on one principal surface;
a second step of forming a first metal layer on the one principal surface of the semiconductor substrate to form a plurality of fuse wirings made of the first metal layer in the groove portion and forming a metal wiring made of the first metal layer on the one principal surface at a position separated from the groove portion of the one principal surface;
a third step of forming a first insulating film so as to cover the one principal surface and have a first opening that exposes the plurality of fuse wirings and a second opening that exposes the metal wiring;
a fourth step of forming a polymeric insulating film in the first opening so as to bury the plurality of fuse wirings in the groove portion;
a fifth step of forming a second metal portion by forming a second metal layer so as to extend covering a first metal portion covering the polymeric insulating film, a surface of the metal wiring exposed in the second opening, and a surface of the first insulating film at a peripheral edge of the second opening;
a sixth step of forming a second insulating film that buries the first metal portion on an upper surface of the polymeric insulating film and covers the second metal portion so as to partially expose an upper surface of the second metal portion; and
a seventh step of forming a third metal portion by forming a third metal layer, the third metal portion ranging from an upper surface of the second metal portion exposed from the second insulating film to an upper surface of the second insulating film.

7. The manufacturing method of a semiconductor device according to claim 6, wherein
the fourth step includes:
a step of forming the polymeric insulating film over an upper side of the groove portion and an upper side of the first insulating film; and
a step of removing the polymeric insulating film in a region other than the upper side of the groove portion.

8. The manufacturing method of a semiconductor device according to claim 6, wherein
the polymeric insulating film is a polyimide film.

9. The manufacturing method of a semiconductor device according to claim 6, wherein
the first insulating film and the second insulating film are oxide films having a thinner film thickness than the polymeric insulating film.

10. The manufacturing method of a semiconductor device according to claim 6, wherein
the first insulating film and the second insulating film are nitride films having a thinner film thickness than the polymeric insulating film.
